(19) United States
(12) Patent Application Publication
(10) Pub. No.: US 2024/0292573 A1
(43) Pub. Date: Aug. 29, 2024

(54) CONTAINER-TYPE DATA CENTER

(71) Applicant: MITSUBISHI HEAVY INDUSTRIES, LTD., Tokyo (JP)

(72) Inventors: Fumito Kajitani, Tokyo (JP); Minoru Matsuo, Tokyo (JP); Naohiko Matsuda, Tokyo (JP); Shinnosuke Osafune, Tokyo (JP)

(73) Assignee: MITSUBISHI HEAVY INDUSTRIES, LTD., Tokyo (JP)

(21) Appl. No.: 18/570,407

(22) PCT Filed: Feb. 14, 2022
(86) PCT No.: PCT/JP2022/005586

§ 371 Date: Dec. 14, 2023

(30) Foreign Application Priority Data
Jun. 17, 2021 (JP) 2021-100665

(51) Int. Cl. H05K 7/20

(52) U.S. Cl. CPC H05K 7/20772; H05K 7/20236; H05K 7/20263; H05K 7/20836

(57) ABSTRACT

A container-type data center includes a container body, a liquid tank rack which is accommodated in the container body and stores a cooling liquid therein, a board which is disposed inside the liquid tank rack to be immersed in the cooling liquid and on which a plurality of electronic components are mounted, a heat exchanger which is accommodated in the container body and cools the cooling liquid guided from the inside of the liquid tank rack and returns the cooling liquid to the liquid tank rack, and a drain pan which is accommodated in the container body and receives the cooling liquid leaking from the liquid tank rack on the lower side of the liquid tank rack.

### TECHNICAL FIELD

The present disclosure relates to a container-type data center that houses an electronic device such as a server.

### BACKGROUND ART

PTL 1 discloses a container-type data center that houses a server. In the container-type data center, the data center can be compactly constituted by housing the server in a standard container and providing a cooling device for cooling the server. In addition, since the container is excellent in portability, there is an advantage in that it is easy to install.

### CITATION LIST

### Patent Literature

[PTL 1] Japanese Patent No. 6293355

### SUMMARY OF INVENTION

### Technical Problem

However, in a case where a liquid immersion method for immersing the server in a cooling liquid is adopted as a method for cooling the server, there is a concern that the cooling liquid may leak from the container.

Further, there is a demand for a liquid immersion cooling device to be compactly housed in the container.

The present disclosure has been made in view of such circumstances, and an object of the present disclosure is to provide a container-type data center capable of preventing cooling liquid from leaking as much as possible.

In addition, an object of the present disclosure is to provide a container-type data center capable of compactly housing a liquid immersion cooling device.

### Solution to Problem

A container-type data center of the present disclosure includes: a container body; a container that is accommodated in the container body and that stores a cooling liquid therein; a board that is disposed to be immersed in the cooling liquid in the container, a plurality of electronic components being mounted on the board; a temperature control unit that is accommodated in the container body, cools the cooling liquid guided from an inside of the container, and returns the cooling liquid to the container; and a drain pan that is accommodated in the container body and that receives the cooling liquid leaking from the container below the container.

### Advantageous Effects of Invention

The drain pan is provided, and thus, it is possible to prevent the cooling liquid from leaking as much as possible.

The liquid immersion cooling device can be compactly housed by separating an electronic component cooling space and a temperature control space with a partition wall member.

### BRIEF DESCRIPTION OF DRAWINGS

FIG. 1 is a schematic diagram illustrating a schematic configuration of a liquid immersion cooling device.

FIG. 2 is a perspective view of a container-type data center including the liquid immersion cooling device of FIG. 1 according to an embodiment of the present disclosure.

FIG. 3 is a perspective view illustrating a liquid tank rack accommodated in the container-type data center of FIG. 2.

FIG. 4 is a perspective view illustrating a drain pan provided in the container-type data center of FIG. 2.

FIG. 5 is a schematic diagram illustrating a disposition of a louver, a filter, and a heat exchanger.

### DESCRIPTION OF EMBODIMENTS

Hereinafter, an embodiment according to the present disclosure will be described with reference to the drawings.

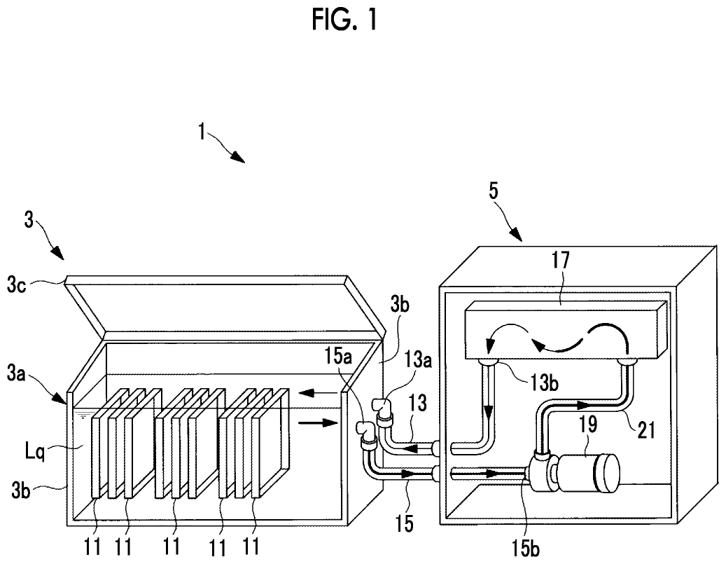

FIG. 1 illustrates a schematic configuration of a liquid immersion cooling device 1 used in a container-type data center. The liquid immersion cooling device 1 includes a liquid tank rack (container) 3 and a pump unit 5.

The liquid tank rack 3 is a bottomed container in which a cooling liquid Lq is stored. The liquid tank rack 3 has a body 3a having a side wall member 3b and an opening-closing lid 3c provided on an upper surface of the body 3a.

As the cooling liquid Lq, a liquid having electrical insulation is used, and, for example, a silicone-based oil or the like is used. The cooling liquid Lq is filled to a height at which an entire board 11 installed in the body 3a of the liquid tank rack 3 is immersed.

The opening-closing lid 3c is opened and closed by rotating around one end thereof.

A plurality of boards 11 are installed in the body 3a of the liquid tank rack 3. The boards 11 are, for example, boards constituting a server, and are arrayed at a predetermined interval in a state where a longitudinal direction is directed to a vertical direction. A plurality of electronic components such as a CPU, a power supply unit, a memory, a storage such as a hard disk or a solid state drive (SSD), and a communication unit constituting the server are mounted on the board 11.

These electronic components generate heat during an operation of the server and are cooled by the cooling liquid Lq.

The pump unit 5 is connected to the liquid tank rack 3 via a liquid supply pipe 13 and a liquid return pipe 15. A downstream end 13a of the liquid supply pipe 13 is connected to the side wall member 3b of the liquid tank rack 3. An upstream end 13b of the liquid supply pipe 13 is connected to a heat exchanger 17 installed inside the pump unit 5.

An upstream end 15a of the liquid return pipe 15 is connected to the side wall member 3b of the liquid tank rack. A downstream end 15b of the liquid return pipe 15 is connected to a liquid pump 19 installed inside the pump unit 5.

The pump unit 5 includes the heat exchanger 17 and the liquid pump 19 described above therein.

The heat exchanger 17 exchanges heat between air taken in from the outside and the cooling liquid supplied from the liquid pump 19 via a cooling liquid discharge pipe 21. The cooling liquid is cooled by exchanging heat with air in the heat exchanger 17. The air introduced into the heat exchanger 17 is guided from the outside.

The liquid pump 19 may be driven by, for example, an electric motor, and a discharge amount may be variable by a control unit (not illustrated).

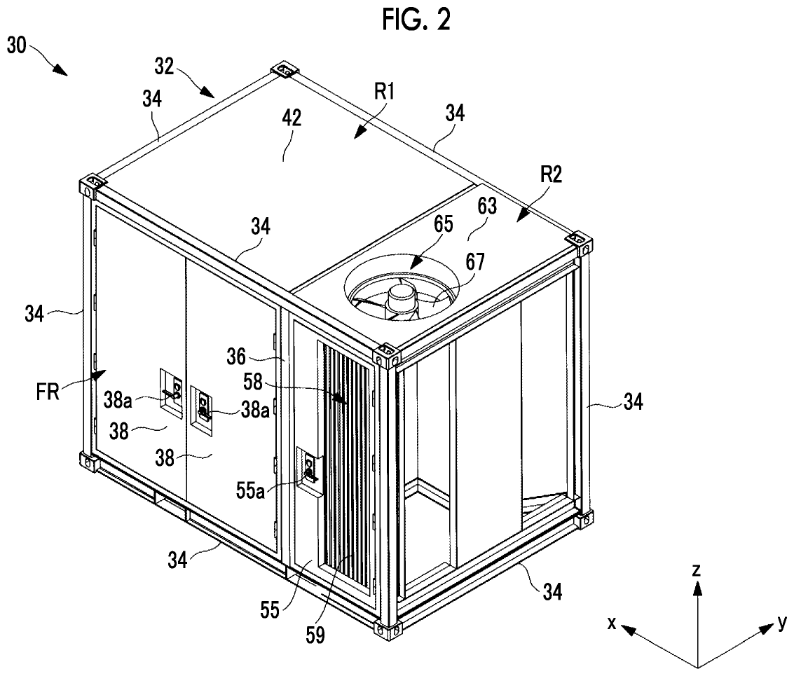

FIG. 2 illustrates a container-type data center 30 that accommodates the liquid tank rack 3 and the pump unit 5 described above. The container-type data center 30 has a standard container shape having portability.

The container-type center 30 includes a container body 32 constituting an outer shape formed into a rectangular body. A width direction (longitudinal direction or x-direction) of the container body 32 is less than or equal to 12 ft (3.66 m). A depth direction (y-direction) of the container body 32 is less than a dimension in the width direction. Each side of the container body 32 formed into the rectangular body is formed by using, for example, frame members (frames) 34 made of a metal square column, and an end portion of each frame member 34 is fixed thereto.

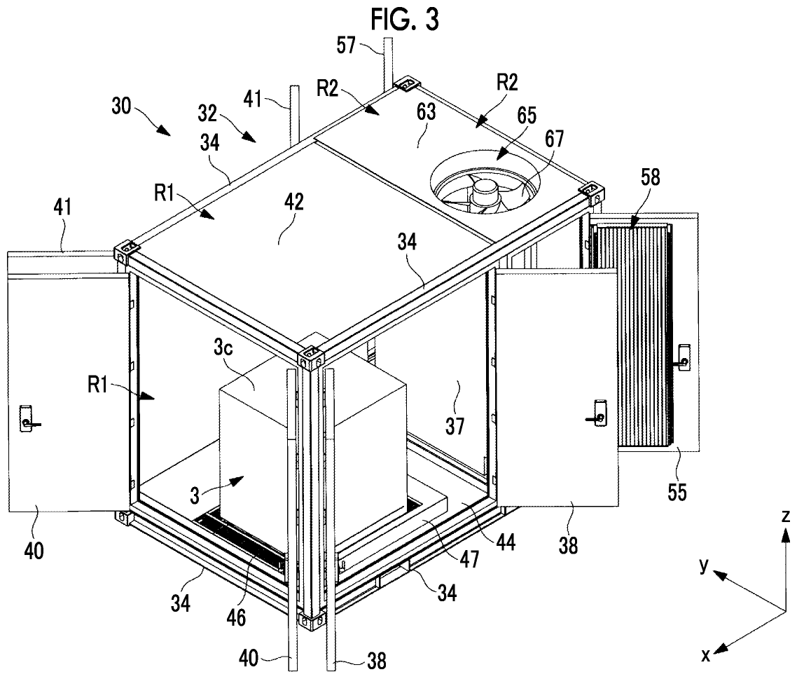

A partition vertical member 36 made of, for example, a metal square column is provided on a front surface FR of the container body 32. The partition vertical member 36 is a structural member for partitioning a server cooling space (electronic component cooling space) R1 where the liquid tank rack 3 is housed and a temperature control space R2 where the pump unit 5 is housed. The partition vertical member 36 extends in an up-down direction (z-direction), and both ends thereof are fixed to the upper and lower frame members 34. Although not illustrated, another partition vertical member 36 is also provided at a symmetrical position on a back surface side of the container body 32. As illustrated in FIG. 3, a flat plate-shaped partition wall member 37 is provided by using these partition vertical members 36. The server cooling space R1 and the temperature control space R2 are partitioned to the left and right by the partition wall member 37. A width direction (x-direction) dimension of the server cooling space R1 is more than or equal to ½ of a width direction dimension of the container body 32, and a width direction dimension of the temperature control space R2 is less than or equal to ½ of a width direction dimension of the container body 32. That is, the width direction dimension of the server cooling space R1 is equal to or more than the width direction dimension of the temperature control space R2.

As illustrated in FIG. 2, in a case where the container body 32 is viewed in front view from the front surface FR side, the server cooling space R1 is positioned on a left side and the temperature control space R2 is positioned on a right side. Each of the server cooling space R1 and the temperature control space R2 can be a closed space.

A server-side front door 38 that is double-opened is provided on the server cooling space R1 side of the front surface FR of the container body 32. A handle 38a with a lock is provided on the server-side front door 38. As illustrated in FIG. 3, a server-side side door 40 that is double-opened is also provided on a left side surface of the server cooling space R1. A server-side rear door 41 that is similarly double-opened is also provided on a back surface of the server cooling space R1. Instead of the doors 38, 40, and 41 provided in the server cooling space R1, any one or two thereof may be used as a fixed wall. An upper portion of the server cooling space R1 is partitioned by a server-side ceiling wall member 42.

As illustrated in FIG. 3, the liquid tank rack 3 described with reference to FIG. 1 is installed in the server cooling space R1. Although not illustrated in FIG. 3, the liquid supply pipe 13 and the liquid return pipe 15 illustrated in FIG. 1 are connected to the liquid tank rack 3. The liquid supply pipe 13 and the liquid return pipe 15 are guided from the temperature control space R2 via the partition wall member 37.

The liquid tank rack 3 is placed on a flat plate-shaped floor member 44. The floor member 44 is installed on upper surfaces of the frame members 34 forming lower sides of the container body 32. A grating 46 is provided in a part of the floor member 44. The grating 46 is provided at a position directly below the liquid tank rack 3. The cooling liquid Lq (see FIG. 1) leaking from the liquid tank rack 3 is guided downward through lattice-shaped openings formed in the grating 46.

A weir portion 47 having a predetermined height is provided to surround the grating 46. The weir portion 47 prevents the cooling liquid Lq from leaking from the grating 46 side to an outer side.

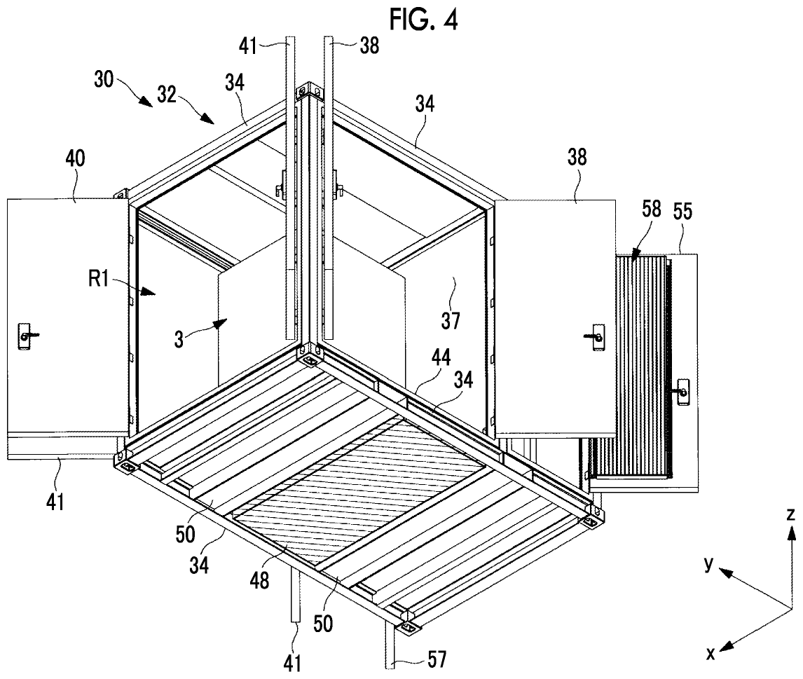

The cooling liquid Lq guided via the grating 46 is received by a drain pan 48 illustrated in FIG. 4. The drain pan 48 is provided below the floor member 44 and has a bottomed container shape. The drain pan 48 is provided between a plurality of support members (frames) 50 extending in a depth direction (y-direction). The support member 50 is a structural member that is provided between the front and rear frame members 34 extending in the x-direction and supports a load of the liquid tank rack 3 or the like. A height (dimension in the z-direction) of the support member 50 is equal to the frame member 34. The drain pan 48 is provided in a space surrounded between the frame members 34 and the support members 50 within a range of the heights of the frame member 34 and the support member 50.

As illustrated in FIG. 2, a temperature control side front door 55 that is half-opened on the temperature control space R2 side is provided in the front surface FR of the container body 32. A handle 55a with a lock is provided on the temperature control side front door 55. As illustrated in FIG. 3, a temperature control side rear door 57 that is half-opened is provided on a back surface of the temperature control space R2. Although not illustrated in FIG. 2 and FIG. 3, a door that is double-opened is provided on a side of the temperature control space R2. Instead of the doors 55 and 57 provided in the temperature control space R2, any one or two thereof may be used as a fixed wall.

As illustrated in FIG. 2, an air intake port 58 is formed in the temperature control side front door 55. A louver 59 is provided in the air intake port 58. The louver 59 has a configuration in which a plurality of blade plates extending in the up-down direction are disposed parallel in the width direction (x-direction) with a predetermined gap. However, an orientation of the blade plate is not limited to the up-down direction, and may be directed to a horizontal direction. The louver 59 removes coarse impurities in the air. The louver 59 is provided over most of the temperature control side front door 55. However, an area where the louver 59 is provided is appropriately set according to a cooling capacity and the like.

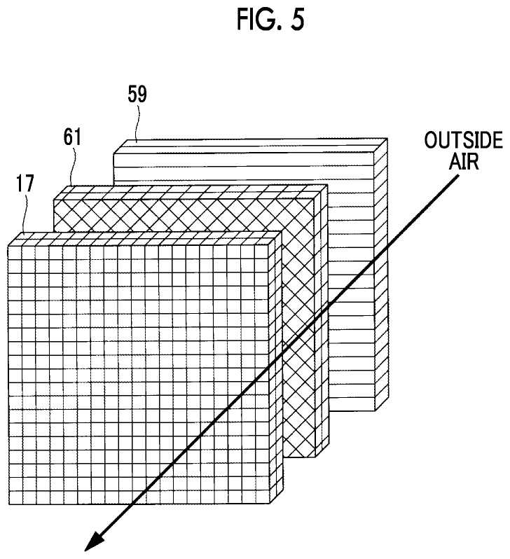

As schematically illustrated in FIG. 5, a filter 61 and the heat exchanger 17 are provided on a back surface side of the louver 59 in this order. That is, an outside air passes through the louver 59, the filter 61, and the heat exchanger 17 in this order.

The filter 61 and the heat exchanger 17 are provided in the air intake port 58 and have a flat plate shape having an area equal to the louver 59. The filter 61 removes fine impurities and moisture in the air that could not be removed by the louver 59. As described with reference to FIG. 1, the heat exchanger 17 is an air-cooling heat exchanger, and, for example, a fin tube type is used. The cooling liquid Lq taken out from the liquid tank rack 3 is cooled by the outside air by the heat exchanger 17.

As illustrated in FIG. 2, an upper surface of the temperature control space R2 is partitioned by a temperature control side ceiling wall member (outer wall portion) 63. For example, a circular exhaust port 65 is formed in the temperature control side ceiling wall member 63. An exhaust fan (exhaust device) 67 is provided in the exhaust port 65. The exhaust fan 67 is driven by an electric motor (not illustrated). A manoeuvre and a rotation speed of the electric motor are controlled by a control unit (not illustrated).

Due to the driving of the exhaust fan 67, the outside air is induced into the temperature control space from the air intake port 58, circulates in the R2 temperature control space R2, and then is exhausted to the outside from the exhaust port 65.

Although not illustrated in FIGS. 2 to 4, the configuration of the pump unit 5 illustrated in FIG. 1, for example, the liquid pump 19, is disposed in the temperature control space R2. The liquid pump 19 is also cooled by the air introduced from the air intake port 58.

The control unit is provided at a predetermined position in the container body 32. However, the control unit may be provided outside the container body 32 and may be connected to a device inside the container body 32 in a wired or wireless manner. The control unit includes, for example, a central processing unit (CPU), a random access memory (RAM), a read only memory (ROM), a computer-readable storage medium, and the like. A series of processing for realizing various functions is stored in a storage medium or the like in the form of a program, as an example, and various functions are realized by the CPU reading out this program to the RAM or the like and executing information processing and calculation. As the program, a form installed in advance in the ROM or other storage medium, a form of being provided in a state of being stored in the computer-readable storage medium, a form of being delivered via wired or wireless communication means, or the like may be applied. The computer-readable storage medium is an SSD, a magnetic disk, a magneto-optical disk, a CD-ROM, a DVD-ROM, a semiconductor memory, or the like.

Next, an operation of the container-type data center 30 having the above configuration will be described.

As illustrated in FIG. 1, the liquid pump 19 is started by a command from the control unit, and thus, the cooling liquid flows and is guided to the heat exchanger 17. In the heat exchanger 17, the cooling liquid Lq is cooled by exchanging heat with the outside air (air) taken in from the air intake port 58 by the exhaust fan 67. The cooling liquid Lq exiting the heat exchanger 17 is guided to the liquid tank rack 3 through the liquid supply pipe 13. The cooling liquid Lq guided to the liquid tank rack 3 flows in the liquid tank rack 3 to cool the electronic components mounted on the board 11.

The cooling liquid Lq that has cooled the electronic components is extracted from the liquid return pipe 15, is guided to the heat exchanger 17 via the liquid pump 19, is cooled, and is guided to the liquid tank rack 3 via the liquid supply pipe 13 again.

The actions and effects of the present embodiment described above are as follows.

Even in a case where the cooling liquid Lq in the liquid tank rack 3 leaks for some reason, the drain pan 48 can receive the leaked cooling liquid below the liquid tank rack 3. As a result, it is possible to prevent the cooling liquid from leaking to the outside of the container body 32 and affecting an external environment as much as possible.

The partition wall member 37 that separates the temperature control space R2 where the heat exchanger 17 is installed from the server cooling space R1 where the liquid tank rack 3 is installed is provided. As a result, power required for the heat exchanger 17 which cools the cooling liquid to function can be reduced. For example, in order to exhaust the air in the temperature control space R2 for cooling the heat exchanger 17, since it is sufficient to exhaust only the temperature control space R2 with the exhaust fan 67 without exhausting the server cooling space R1, facility power can be reduced.

The air intake port 58 is formed in the temperature control side front door 55 forming the temperature control space R2, and the heat exchanger 17 for cooling the cooling liquid is installed in the air intake port 58. The temperature control space R2 can be reduced by limiting an installation space of the heat exchanger 17 to the temperature control side front door 55.

The exhaust port 65 is formed in the temperature control side ceiling wall member 63 at a position different from the air intake port 58, and the exhaust fan 67 is installed in the exhaust port 65. As a result, the air induced by the exhaust of the exhaust fan 67 is introduced into the temperature control space R2 from the air intake port 58. Accordingly, it is possible to uniformly take in the air from the air intake port 58 as compared with a case where a suction fan is provided in the air intake port 58. As a result, the efficiency of the heat exchanger 17 provided in the air intake port 58 is improved. A position where the exhaust port 65 is provided is not limited to the temperature control side ceiling wall member 63, and may be a wall member or a door different from the temperature control side front door 55 where the air intake port 58 is provided.

The louver 59 and the filter 61 are provided on an air flow upstream side of the heat exchanger 17, and thus, impurities and moisture associated with the air flowing in from the air intake port 58 can be removed. As a result, failure and corrosion of the device installed in the temperature control space R2 and an inner wall forming the temperature control space R2 are suppressed.

A space having a predetermined height is formed between the frame members 34 and the support members 50. The drain pan 48 is provided in this space, and thus, the drain pan 48 can be installed in a space-efficient manner. The container-type data center described in the embodiment described above is understood as follows, for example.

A container-type data center (30) according to one aspect of the present disclosure includes: a container body (32); a container (3) that is accommodated in the container body and that stores a cooling liquid therein; a board (11) that is disposed to be immersed in the cooling liquid in the container, a plurality of electronic components s being mounted on the board; a temperature control unit (17) that is accommodated in the container body, cools the cooling liquid guided from an inside of the container, and returns the cooling liquid to the container; and a drain pan (48) that is accommodated in the container body and that receives the cooling liquid leaking from the container below the container.

The electronic component mounted on the board disposed in the container is cooled by the cooling liquid. The cooling liquid is cooled by the temperature control unit and is returned to the container, and the temperature of the cooling liquid in the container is maintained at a desired value.

Although the cooling liquid is held in the container, even in a case where the cooling liquid leaks for some reason, the drain pan that receives the leaked cooling liquid below the container is provided. As a result, it is possible to prevent the cooling liquid from leaking to the outside of the container body and affecting the external environment as much as possible.

The size of the container is, for example, a maximum dimension of 12 ft (3.66 m) or less.

In the container-type data center according to one aspect of the present disclosure, a partition wall member (37) that separates a temperature control space (R2) where the temperature control unit is installed from an electronic component cooling space (R1) where the container is installed is provided.

The partition wall member that separates the temperature control space where the temperature control unit is installed from the electronic component cooling space where the container is installed is provided. As a result, the power required for the temperature control unit which cools the cooling liquid to function can be reduced. For example, in a case where the exhaust device for exhausting the air in the temperature control space is provided for temperature control, since it is sufficient to exhaust only the temperature control space, the facility power can be reduced.

In the container-type data center according to one aspect of the present disclosure, an air intake port (58) is formed in a door or an outer wall portion forming the temperature control space, and a heat exchanger (17) that cools the cooling liquid is installed in the air intake port.

The air intake port is formed in the door or the outer wall portion that forms the temperature control space, and the heat exchanger that cools the cooling liquid is installed in the air intake port. The temperature control space can be reduced by limiting the installation space of the heat exchanger to the door or the outer wall portion.

In the container-type data center according to one aspect of the present disclosure, an exhaust port is formed in the door or the outer wall portion at a position different from the air intake port, and an exhaust device that exhausts air in the temperature control space to an outside is installed in the exhaust port.

The exhaust port is formed in the door or the outer wall portion at the position different from the air intake port, and the exhaust device is installed in the exhaust port. As a result, the air induced by the exhaust of the exhaust device is introduced into the temperature control space from the air intake port. Accordingly, it is possible to uniformly take in the air from the air intake port as compared with a case where the suction fan is provided in the air intake port. As a result, the efficiency of the heat exchanger provided in the air intake port is improved.

In the container-type data center according to one aspect of the present disclosure, a louver (59) and a filter (61) are provided on an air flow upstream side of the heat exchanger.

The louver and the filter are provided on the air flow upstream side of the heat exchanger, and thus, the impurities and moisture associated with the air flowing in from the air intake port can be removed. As a result, the failure and corrosion of the device installed in the temperature control space and the inner wall forming the temperature control space are suppressed.

The container-type data center according to one aspect of the present disclosure further includes a plurality of frames (34 and 50) that are provided below the container, and the drain pan is provided in a space formed between the frames.

The space having the predetermined height is formed between the frames. The drain pan is provided in this space, and thus, the drain pan can be installed in a space-efficient manner.

### REFERENCE SIGNS LIST

1 liquid immersion cooling device
3 liquid tank rack (container)
3a body
3b side wall member
3c opening-closing lid
5 pump unit
11 board
13 liquid supply pipe
13a downstream end
13b upstream end
15 liquid return pipe
17 heat exchanger
19 liquid pump
21 cooling liquid discharge pipe
30 container-type data center
32 container body
34 frame member (frame)
36 partition vertical member
37 partition wall member
38 server-side front door
38a handle
40 server-side side door
41 server-side rear door
42 server-side ceiling wall member
44 floor member
46 grating
48 drain pan
50 support member (frame)
55 temperature control side front door
57 temperature control side rear door
58 air intake port
59 louver
61 filter
63 temperature control side ceiling wall member (outer wall portion)
65 exhaust port
67 exhaust fan (exhaust device)
ER front surface
Lq cooling liquid
R1 server cooling space (electronic component cooling space)
R2 temperature control space

1. A container-type data center comprising:
a container body;
a container that is accommodated in the container body and that stores a cooling liquid therein;
a board that is disposed to be immersed in the cooling liquid in the container, a plurality of electronic components being mounted on the board;
a temperature control unit that is accommodated in the container body, cools the cooling liquid guided from an inside of the container, and returns the cooling liquid to the container; and
a drain pan that is accommodated in the container body and that receives the cooling liquid leaking from the container below the container.

2. The container-type data center according to claim 1, wherein a partition wall member that separates a temperature control space where the temperature control unit is installed from an electronic component cooling space where the container is installed is provided.

3. The container-type data center according to claim 2, wherein
an air intake port is formed in a door or an outer wall portion forming the temperature control space, and
a heat exchanger that cools the cooling liquid is installed in the air intake port.

4. The container-type data center according to claim 3, wherein
an exhaust port is formed in the door or the outer wall portion at a position different from the air intake port, and
an exhaust device that exhausts air in the temperature control space to an outside is installed in the exhaust port.

5. The container-type data center according to claim 3, wherein a louver and a filter are provided on an air flow upstream side of the heat exchanger.

6. The container-type data center according to claim 1, further comprising:
a plurality of frames that are provided below the container, wherein
the drain pan is provided in a space formed between the frames.
